(19) United States
(12) Patent Application Publication
(10) Pub. No.: US 2003/0168175 A1
(43) Pub. Date: Sep. 11, 2003

(54) Substrate alignment apparatus

(76) Inventors: Kyung-Tae Kim, Suwon City (KR); Hung The Nguyen, Fremont, CA (US)

Correspondence Address: Patent Counsel, Applied Materials, Inc., P.O. Box 450-A, Santa Clara,, CA, 95052, US

(21) Appl. No.: 10/094,156

(22) Filed: Mar. 8, 2002

(51) Int. Cl. C23F 1/00; C23C 16/00

(52) U.S. Cl. 156/345.51; 118/728

(57) ABSTRACT

A substrate support that aligns a substrate placed thereon is generally provided. In one aspect, a substrate support for supporting a substrate includes a support plate, an alignment member and a cylindrical member. The alignment member is disposed proximate a first edge of the support plate while the cylindrical member is disposed proximate an adjacent, second edge of the support plate. The alignment member extends above the support plate and is adapted to urge the substrate in a first direction. The cylindrical member has a rotational axis aligned with the first direction. In another aspect of the invention, a load lock chamber is provided that includes a chamber body having a first and a second substrate transfer ports. A support plate is disposed in the chamber body and has a substrate alignment mechanism interacting therewith that aligns the substrate on the support plate.

### CROSS REFERENCE TO OTHER RELATED APPLICATIONS

This application is related to U.S. patent application Ser. No. ______, filed Feb. 22, 2002 (Attorney Docket No. 6885/AKT/DISLAY/BG), entitled “SUBSTRATE SUPPORT”, which is hereby incorporated by reference in its entirety.

### FIELD OF THE INVENTION

Embodiments of the invention generally relate to a substrate alignment apparatus.

### BACKGROUND OF THE INVENTION

Thin film transistors (TFTs) are conventionally made on large glass substrates or plates for use in monitors, flat panel displays, solar cells, personal digital assistants (PDAs), cell phones and the like. TFTs are made in a cluster tool by sequential deposition of various films including amorphous silicon, doped and undoped silicon oxides, silicon nitride and the like in a plurality of vacuum process chambers typically arranged around a central transfer chamber. The cluster tool is typically coupled to a factory interface that includes a plurality of substrate storage cassette that holds substrates before and after processing. A load lock chamber is generally disposed between the factory interface and cluster tool to facilitate substrate transfer between a vacuum environment of the cluster tool and an atmospheric environment of a factory interface.

The positioning of glass substrates used for displays in a load lock chamber is difficult as compared to smaller, 200 mm and even 300 mm circular substrates. For example, as glass substrates often have dimensions exceeding 550 mm by 650 mm, with trends towards 1.2 square meters and larger, small deviations in position may result in significant substrate misalignment. A misaligned substrate has high probability of damage, resulting in a costly loss of the substrate. Moreover, a misaligned substrate must be manually removed from the load lock chamber, thereby requiring costly loss of production time and diminished substrate throughput.

Typically, the accuracy of substrate placement is controlled by a robot disposed in the factory interface that is utilized to move substrates between the cassettes and the load lock. However, many end-users of cluster tools are now providing the factory interface and robot disposed therein. Thus, if the accuracy and repeatability of substrate placement by the user supplied robot is not within the designed specifications of the load lock chamber, substrate damage is likely. It would be desirable for the load lock chamber to be more compatible with regard to substrate placement so that tool components (i.e., user provided factory interfaces) may be used in order to reduce system costs while increasing design flexibility.

Therefore, there is a need for a load lock chamber and substrate support that corrects the orientation and position of substrates placed thereon.

### SUMMARY OF THE INVENTION

A substrate support that aligns a substrate placed thereon is generally provided. In one embodiment, a substrate support for supporting a substrate includes a support plate, a first alignment member, a second alignment member and a cylindrical member. The first alignment member is disposed proximate a first edge of the support plate while the second alignment member is disposed proximate a second edge of the support plate. The cylindrical member is disposed proximate a third edge disposed between the first and second edges of the support plate. The first alignment member extends above the support plate and is adapted to urge the substrate in a first direction while the second alignment member is adapted to urge the substrate in a second direction opposite the first direction, thereby aligning the substrate therebetween. The cylindrical member has a rotational axis aligned with the first direction and is adapted to urge the substrate in a third direction to facilitate movement of the substrate laterally between the first and second alignment members.

In another aspect of the invention, a load lock chamber is provided. In one embodiment, a load lock chamber includes a chamber body having a first and a second substrate transfer port. A support plate is disposed in the chamber body and has a first surface adapted to support the substrate passed through either the first or second substrate transfer port. A first alignment member is disposed proximate a first edge of the support plate and extends above a plane of the first surface of the support plate. The alignment member is adapted to urge the substrate in a first direction. A second alignment member is disposed proximate a second edge of the support plate opposite the first alignment member and is adapted to urge the substrate in a direction opposite the first direction. A first cylindrical member is disposed proximate a third edge of the support plate and has a rotational axis aligned with the first direction. A second cylindrical member is disposed proximate a fourth edge of the support plate opposite the third edge. The second cylindrical member has a rotational axis aligned with the first direction. The first and second alignments center the substrate therebetween along a first coordinate axis while the first and second cylindrical members center the substrate therebetween along a second coordinate axis that is different than the first coordinate axis, thereby cooperatively aligning the substrate relative to the support plate.

### BRIEF DESCRIPTION OF THE DRAWINGS

So that the manner in which the above recited features of the present invention are attained and can be understood in detail, a more particular description of the invention, briefly summarized above, may be had by reference to the embodiment thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cluster tool having one embodiment of a load lock chamber coupled the cluster tool to a factory interface;

FIG. 2 is a sectional view of the load lock chamber of FIG. 1;

FIG. 3 is an isometric view of a first support plate having one embodiment of an alignment apparatus;

FIG. 4 is a side view of the first support plate of FIG. 3; and

FIG. 5 is a sectional view of the first support plate taken along section line 5-5 of FIG. 4.

To facilitate understanding, identical reference numerals have been used, wherever possible, to designate identical elements that are common to the figures.

### DETAILED DESCRIPTION

The invention generally provides a substrate support having an alignment mechanism that aligns or centers a substrate disposed thereon to a predetermined position. The invention is illustratively described below utilized in a dual substrate load lock chamber, such as those available from AKT, a division of Applied Materials, Inc., Santa Clara, Calif. However, it should be understood that the invention has utility in other configurations, for example, single substrate load lock chambers, multiple substrate load lock chambers, robot hand-off platforms, buffer stations and other devices utilized to support a substrate where the positional accuracy of the substrate is desired.

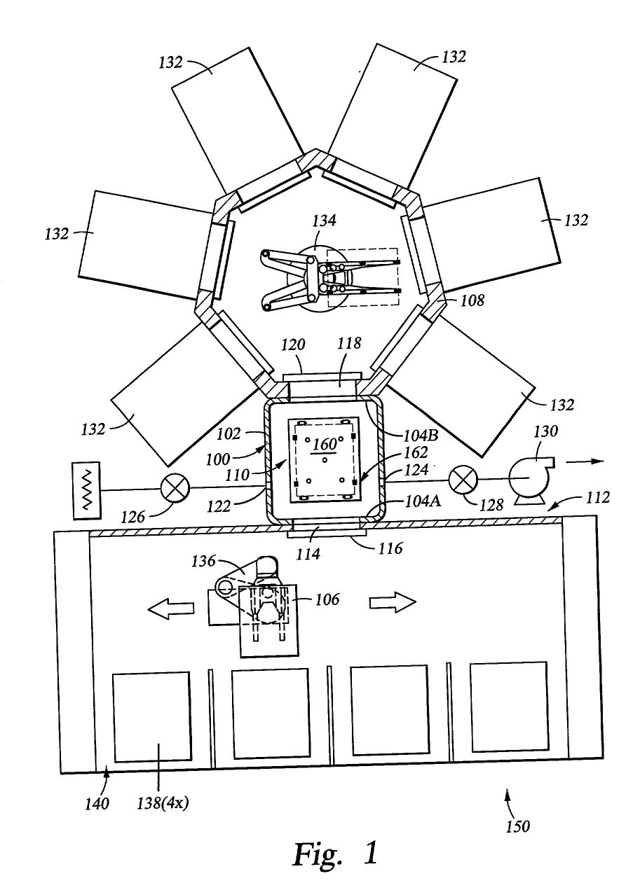

FIG. 1 is a cross sectional view of one embodiment of a process system 150. The process system 150 typically includes a transfer chamber 108 coupled to a factory interface 112 by a load lock chamber 100 that has a substrate alignment apparatus 162. The transfer chamber 108 has at least one vacuum robot 134 disposed therein that is adapted to transfer substrates between a plurality of circumscribing process chambers 132 and the load lock chamber 100. In one embodiment, one of the process chambers 132 is a pre-heat chamber that thermally conditions substrates prior to processing to enhance throughput of the system 150. Typically, the transfer chamber 108 is maintained at a vacuum condition to eliminate the necessity of adjusting the pressures between the transfer chamber 108 and the individual process chambers 132 after each substrate transfer.

The factory interface 112 generally includes a plurality of substrate storage cassettes 138 and an atmospheric robot 136. The cassettes 138 are generally removably disposed in a plurality of bays 140 formed on one side of the factory interface 112. The atmospheric robot 136 is adapted to transfer substrates 106 between the cassettes 138 and the load lock chamber 100. Typically, the factory interface 112 is maintained at or slightly above atmospheric pressure.

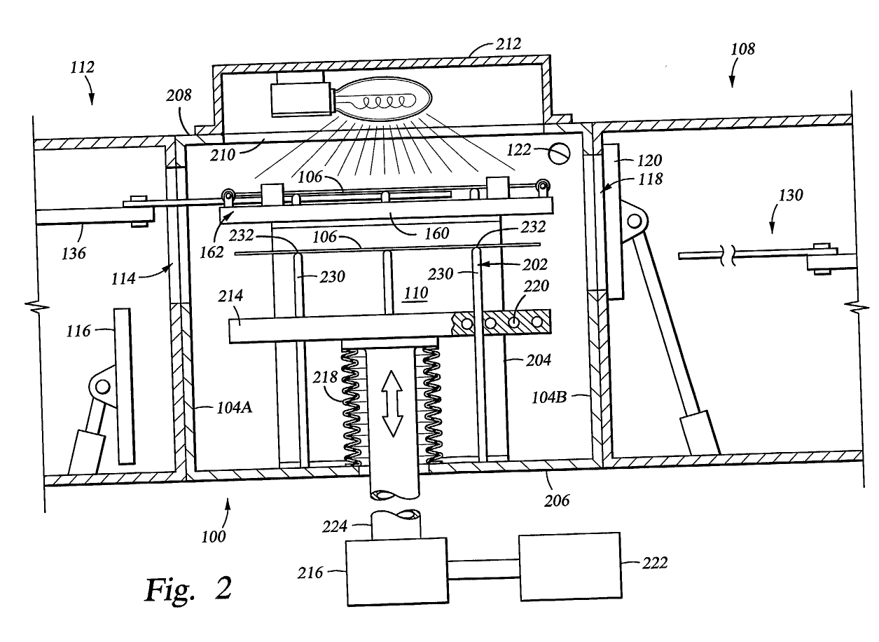

FIG. 2 is a sectional view of one embodiment of the load lock chamber 100. The load lock chamber 100 includes a body 102 having walls 104A, 104B, a bottom 206 and a top 208 that define a sealable internal volume 110. The load lock chamber 100 is typically coupled to a factory interface 112 through a port 114 disposed in the wall 104A. A slit valve 116 selectively seals the port 114 to isolate the atmospheres of the internal volume 110 of the load lock chamber 100 and the factory interface 112. The slit valve 116 may be opened to allow a substrate 106 to pass through the port 114 between the factory interface 112 and the load lock chamber 100.

The load lock chamber 100 is typically coupled to the transfer chamber 108 through a port 118 disposed in the wall 104B. A slit valve 120 selectively seals the port 118 to selectively isolate the atmospheres of the internal volume 110 of the load lock chamber 100 and the transfer chamber 108. The slit valve 120 may be opened to allow the substrate 106 to pass between the transfer chamber 108 and the load lock chamber 100. Examples of slit valves that may be adapted to benefit from the invention are described in U.S. Pat. No. 5,579,718, issued Dec. 3, 1996 to Freerks and U.S. Pat. No. 6,045,620, issued Apr. 4, 2000 to Tepman et al., both of which are hereby incorporated by reference in their entireties.

The chamber body 102 additionally includes at least one port disposed therethrough to facilitate controlling the pressure within the interior volume 110. In the embodiment depicted in FIG. 1, the chamber body 102 includes a vent port 122 and a vacuum port 124 formed through the chamber body 102. Valves 126, 128 are respectfully coupled to the vent port 122 and vacuum port 124 to selectively prevent flow therethrough. The vacuum port 122 is coupled to a vacuum pump 130 that is utilized to selectively lower the pressure within the interior volume to a level that substantially matches the pressure of the transfer chamber 108. When the pressures between the transfer chamber 108 and the load lock chamber 100 are substantially equal, the slit valve 120 may be opened to allow processed substrates to be transferred to the load lock chamber 100 and substrates to be processed transferred to the transfer chamber 108 by the vacuum robot 124.

After placing the substrate returning from the transfer chamber 108 in the load lock chamber 100, the slit valve 120 is closed and the valve 126 is opened thereby allowing air into the load lock chamber 100 and raising the pressure within the internal volume 110. Typically, the air entering the interior volume 110 through the vent port 122 is filtered to minimize potential particulate contamination of the substrate. Once the pressure within in the load lock chamber 100 is substantially equal to that of the factory interface 112, the slit valve 116 opens, thus allowing the atmospheric robot 136 to transfer of substrates between the load lock chamber 100 and the substrate storage cassettes 138 coupled to the factory interface 112.

In order to minimize the precision and accuracy required of the atmospheric robot 136, a support plate 160 disposed within the load lock chamber 100 and adapted to receive substrates from the atmospheric robot 136, is equipped with at least one alignment apparatus 162 that positions the substrate 106 relative to the support plate 160. For example, the alignment apparatus 162 may correct positional inaccuracies between a deposited position of the substrate 106 as placed by the atmospheric robot 136 on the support plate 160 and a predefined (i.e., designed) position of the substrate 106 relative the support plate 160. Having the position of the substrate 106 aligned by the alignment apparatus 162 within the load lock chamber 100 independent from conventional correction methods that utilize the atmospheric robot 136 to adjust the substrate placement allows greater flexibility and lower system costs. For example, the support plate 160 with alignment apparatus 162 provides greater compatibility between the load lock chamber 100 and user supplied factory interfaces 112 since the load lock chamber 100 is more tolerant to substrate position on the support plate 160, thereby reducing the need for robots of great precision and/or corrective robot motion algorithms generated by the factory interface provider. Moreover, as the positional accuracy designed criteria for the atmospheric robot 136 is diminished, less costly robots may be utilized.

The first support plate 160 shown in FIG. 2, has the alignment apparatus 162 disposed over a second substrate support 202 in a dual substrate handling configuration. Embodiments of the invention, however, includes at least one substrate support plate having an alignment mechanism, which may be utilized with zero or a plurality of additional support plates, some, all or none of which may include alignment mechanisms.

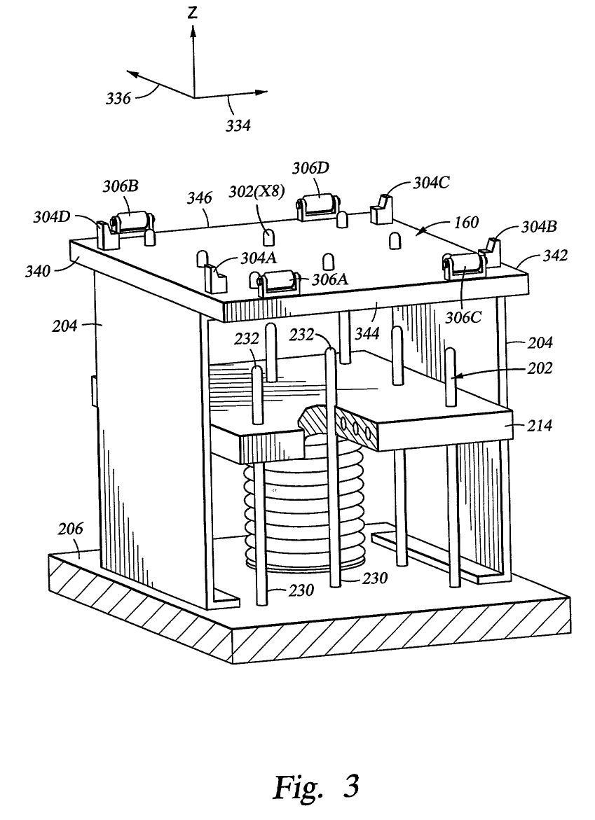

The first support plate 160 and the second support 202 are generally configured to respectively hold substrates in a stacked parallel orientation within the load lock chamber 100 in a position accessible to both the atmospheric and vacuum robots 136, 134. Typically, the first support plate 160 is utilized for holding substrates entering the transfer chamber 106 while the second support 202 is utilized for holding substrates returning to the factory interface 112. The first support plate 160 is coupled to the chamber body 102, typically to the bottom 206. As seen in FIGS. 2 and 3, stanchions 204 couple the first support plate 160 to the chamber bottom 206. The stanchions 204 are generally positioned in a spaced-apart relationship to facilitate placement of a substrate on the second support 202. The stanchions 204 are additionally spaced wide enough to allow movement of the cooling plate 214 therebetween.

The second support 202 generally holds a substrate between the first support plate 160 and the chamber bottom 206. The second support 202 may be a plate supported by the stanchions 204 or other member. In the embodiment depicted in FIGS. 2 and 3, the second support 202 comprises a plurality of substrate support posts 230 coupled to the chamber bottom 206, each post 230 having a distal end 232 defining a generally planar, substrate supporting surface. The posts 230 are generally arranged not to interfere with the robots 134, 136 during substrate transfer.

Thermal control of the substrates may additionally be practiced within the load lock chamber 100. For example, the top 208 of the chamber body 102 may include a window 210 having a radiant heater 212 mounted thereover. The heater 212 illuminates the substrate through the window 210 to heat the substrate disposed on the first support plate 160. A cooling plate 214 may additionally be disposed between the first support plate 160 and the bottom 206 of the chamber body 102. The cooling plate 214 includes a plurality of apertures 228 formed therethrough that allow the posts 230 to be disposed through the cooling plate 214. Typically, the cooling plate 214 is coupled to a lift mechanism 216 disposed outside the load lock chamber 100. The lift mechanism 216 may be actuated to move the cooling plate 214 along the posts 230. The lift mechanism 216 moves the cooling plate 214 in close proximately to the substrate retained on the distal ends 232 of the second support 202 thereby cooling the substrate prior to handling by the atmospheric robot. Optionally, the cooling plate 214 may lift the substrate off of the section support 202 to maximize heat transfer. Typically, the cooling plate 214 is coupled to the bottom 206 of the chamber body 102 by a dynamic seal, for example, a bellows 218. In one embodiment, the cooling plate 214 includes one or more conduits 220 coupled to a heat transfer fluid source 222 through a shaft 224 that couples the cooling plate 214 to the lift mechanism 216. Fluid, from the fluid source 222, is flowed through the conduits 220 to remove heat transferred from the substrate to the second support 202.

FIG. 3 depicts an isometric view of the first support plate 160 and the second support 202. The first support plate 160 generally includes a plurality of support elements 302 that are adapted to maintain the substrate in a spaced-apart relation relative to the first support plate 160. The height of the support elements 302 is generally configured to allow a blade of the robots 136, 134 between the substrate seated on the support elements 302 and the support plate 160. Optionally, channels may be formed the support plate 160 between the support elements 302 to provide space of the blade of the robots 136, 134. The support elements 302 additionally allow the substrate to move parallel to a plane of the first support plate 160 without scratching or otherwise damaging the substrates. The support elements 302 may be low friction pads, roller balls or air bearings among others. In the embodiment depicted in FIG. 3, the support elements 302 are fabricated from stainless steel or a polymer, for example, fluoropolymers or polyetherether ketone. The distal ends 232 of the second support 202 may also include support elements 302 to minimize potential damage to the substrate.

The first support plate 160 is typically circumscribed by a plurality of alignment apparatus 162. The alignment apparatus 162 may be coupled to the support plate 160 or alternatively to a portion of the chamber body 102. The alignment apparatus 162 are adapted to cooperatively ensure placement of a substrate in a predetermined position relative to the support plate 160. Generally, a first pair of alignment devices are configured to align a substrate along a first coordinate axis 334 while a second pair of alignment devices are configured to align the substrate therebetween in a second coordinate axis 336, thereby cooperatively moving the substrate into a predetermined position relative to the support plate 160. Typically, the first coordinate axis 334 is orientated perpendicular to the second coordinate axis 336.

Generally, a first alignment apparatus 330 includes at least a first alignment member 304A and a second alignment member 304B disposed across opposite sides of the support plate 160. The alignment members 304A-B are positioned respectively along a first edge 340 and a second edge 342 of the support plate 160, and cooperatively align the substrate therebetween along the first coordinate axis 334. A second alignment apparatus 332 generally includes a first cylinder 306A and a second cylinder 306B disposed across a third 344 and an opposing fourth side 346 of the support plate 160. The first and second cylinders 306A-B cooperatively align the substrate therebetween along the second coordinate axis 336 that is different than the first coordinate axis 334. The first and second alignment apparatus 330, 332 cooperatively align the substrate in a predetermined position relative to the support plate 160 in a position that facilitates further handling and processing of the substrate without damage due to substrate misalignment.

In the embodiment depicted in FIG. 3, the first alignment apparatus 330 and the second alignment apparatus 332 are disposed across the four edges 340, 342, 344, 346 of the support plate 160. Each alignment apparatus 330, 332 generally includes at least two alignment members 304A-D and at least two cylinders 306A-D. The set of alignment members and cylinders comprising each alignment apparatus are typically coupled to a first surface 308 of the support plate 160 on adjacent edges of the support plate 160 and are adapted to move a mis-positioned substrate into a predetermined position. Typically, the alignment member and cylinder comprising each alignment apparatus are adapted to move the substrate in orthogonal directions, however, the alignment member and cylinder may be configured to move the substrate in other directions.

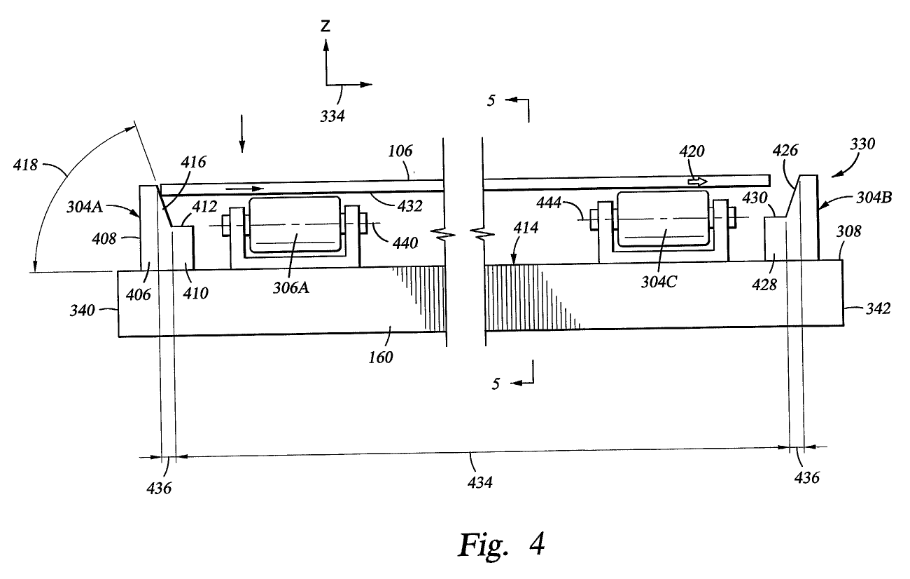

FIG. 4 depicts a sectional view of the support plate 160 having the first alignment apparatus 330 disposed across opposing sides 340, 342 of the support plate 160. The first alignment apparatus 330 generally includes the first alignment member 304A and the second alignment member 304B. The first alignment member 304A is coupled along the first edge 340 of the support plate 160. The first alignment member 304A is generally fabricated from or at least partially coated with a material that minimizes marring, scratching or contamination of the substrate. In one embodiment, the first alignment member 304A is fabricated from stainless steel or a polymer, for example, fluoropolymers or polyetherether ketone.

The first alignment member 304A generally includes a first portion 406 and a second portion 408. The first portion 406 is generally coupled to the first surface 308 of the first support plate 160. The first portion 406 may include a plateau 410 having a top surface 412 orientated substantially parallel to the support plate 160. The top surface 412 is typically at an elevation above the first surface 308 of the first support plate 160 that is about equal to or greater than an elevation of the support elements 302. Optionally, the top surface 412 may taper towards the center 414 of the first support plate 160.

The second portion 408 of the first alignment member 304A generally projects above the first surface 308 of the first support plate 160 and the plateau 410. The second portion 408 includes a sloping face 416 that is disposed at an acute angle relative to the first surface 308 of the support plate 160. In one embodiment, the angle of the sloping face 416 is about 60 to about 80 degrees. Generally, the sloping face 416 is adapted to move the substrate 106 contacting therewith in a first direction 420, generally toward the center 414 of the support plate 160.

The second alignment member 304B is disposed opposite the first alignment member 304A on a second edge 342 of the support plate 160. The second alignment member 304B includes a plateau 428, a top surface 430 and a sloping face 426 disposed on the support plate 160 and is typically configured in a mirror image relative to the first alignment member 304A about the center 414 of the support plate 160. Thus, the sloping face 426 of the second support member 304B is adapted to move a substrate contacting therewith in a direction opposite the first direction 420.

A working distance 434 between intersections of opposing plateaus and sloping faces of the first and second alignment members 304A, 304B is generally configured to be about equal to a positional tolerance of designed parameters for substrate location relative to the support plate 160 in the direction between the members 304A, 304B. A correction range 436 is generally the distance over which the sloping faces 416, 426 will move an out-of-position substrate into the working distance 434. For example, as an out-of alignment substrate 106 is lowered onto the support plate 160 by the atmospheric robot (not shown), the substrate 106 contacts the sloping face 416 of the first closest alignment member, for example, the first alignment member 304A. The angle 418 of the sloping face 416 urges the substrate 106 in the first direction 420 to capture the substrate between the opposing second alignment member 304B. The substrate 106 continues to move along the sloping face 416 until a bottom 432 of the substrate 106 become seated on the plateaus 410, 428 of the first and second alignment members 304A, 304B, at which point, the substrate 106 has moved within the working distance 434 and is correctly positioned (with respect to an coordinate axis defined by the first direction) for safe transfer without damage. The other alignment members are similarly configured.

The first cylinder 306A is generally coupled to the support plate 160 and has a rotational axis 440 aligned with the first direction 420 (i.e., the rotational axis 440 is within a few degrees of the first direction 420). In one embodiment, the axis 440 is parallel to the first direction 420. The orientation of the axis 440 may alternatively be disposed at an acute angle with the first direction 440. In one embodiment, the axis 440 is positioned at an elevation relative the first surface 308 of the support plate 160 about equal to or slightly less than the elevation of the top surface 412 of the plateau 410 of the first alignment element 304A. The first cylinder 306A may be fabricated from stainless steel or a polymer, for example, fluoropolymers or polyetherether ketone.

Typically, the first cylinder 306A is positioned along an edge of the support plate 160 adjacent the first edge 340 along which the first alignment member 304A is disposed. The first cylinder 306A is generally positioned so that at least a portion of the cylinder is inwards of the intersection of the sloping face 416 and the top surface 412. The third cylinder 306C is generally positioned along the same edge of the support plate 160 as the first cylinder 306A.

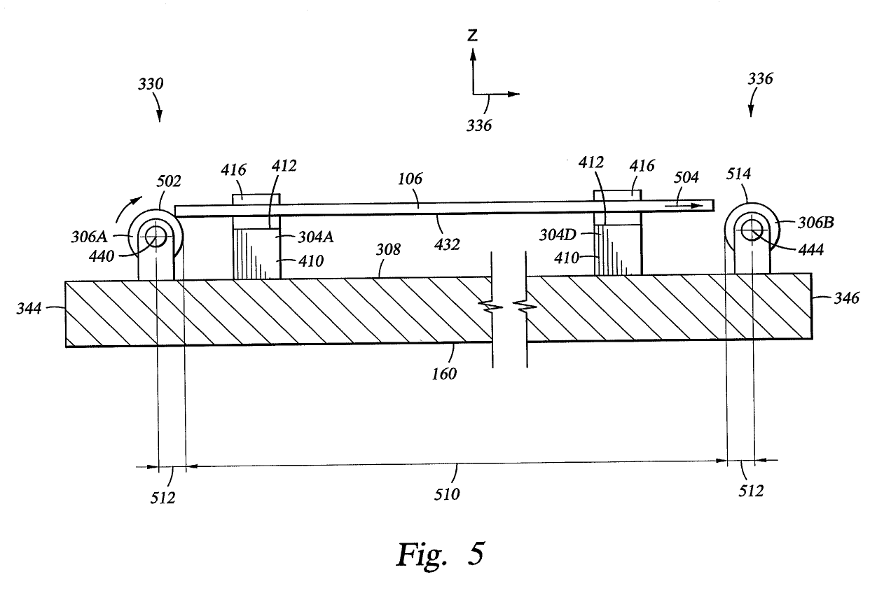

FIG. 5 is a sectional view of the support plate 160 illustrating the interaction between the substrate 106 and the first and second cylinders 306A and 306B. The first and second the first and second cylinders 306A-B are generally positioned across opposite edges of the support plate 160 and cooperatively align the substrate therebetween along a second coordinate axis 336 that is different than the first coordinate axis 334. The cylinders 306A-B may be used in conjunction with the first and second alignment members 304A-B to cooperatively align the substrate in a predetermined position relative to the support plate 160 in a position that facilitates further handling and processing of the substrate without damage due to substrate misalignment.

The first cylinder 306A is generally coupled to the support plate 160 along a third edge 344 that couples the first and second edges 340, 342 shown in FIG. 4. The rotational axis 440 of the first cylinder 306A is typically disposed parallel to the third edge 344. The first cylinder 306A has an outer diameter 502 that is adapted to move a substrate in contact therewith in a second direction 504 that is typically, but not exclusively, orthogonal to the first direction 420 depicted in FIG. 4. The outer diameter 502 of the first cylinder 306A is typically fabricated or coated with a material that does not scratch, mar or otherwise contaminate the substrate 106. The second cylinder 306B is generally positioned along a fourth edge 346 of the support plate 160 opposite the third edge 344. The third cylinder 306D includes an outer diameter 514. The outer diameter 514 is adapted to move a substrate in contact therewith in a direction opposite the second direction 504. Thus, the first and second cylinders 306A-B may cooperatively move a substrate therebetween to a predetermined position.

A working distance 510 defined between the outer diameters 502, 514 of the first and second cylinders 304A, 304B is generally configured to be about equal to the positional tolerance of designed parameters for substrate location relative to the support plate 160 along the second coordinate axis 336 defined between the cylinders 304A, 304B. A correction range 512 is generally distance over which the cylinders 306A, 306B will move an out-of-position substrate into the working distance 510. The diameter of the correction range 512 is equal to or slightly less than the diameter of the cylinders 306A, 306B. The diameter of the cylinders 306A, 306B should be selected as not to stick up too high as to interfere with the substrate when transported by either the robots 134, 136 shown in FIG. 1. For example, as an out-of alignment substrate 106 is lowered onto the support plate 160 by the atmospheric robot (not shown), the substrate 106 contacts the outer diameter 502 of the closest cylinder, for example, the first cylinder 306A. The offset between the point of contact between the substrate 106 and the outer diameter 502 and the rotational axis 440 causes the first cylinder 306A to rotate, thus urging the substrate 106 in the second direction 504 toward the center of the support plate 160 and the second cylinder 306B. The substrate 106 continues to move in the second direction 504 as the cylinder 306A rotates until the bottom 432 of the substrate 106 become seated on the plateaus of the first and second alignment members 304A, 304B, at which point, the substrate 106 has moved within the working distance 510 and is correctly positioned for safe transfer without damage with respect to the second coordinate axis 336.

While the forgoing is directed to the some embodiments of the present invention, other and further embodiments of the invention may be devised without departing from the basic scope thereof, and the scope thereof is determined by the claims that follow.

What is claimed is:

1. A substrate support for supporting a substrate, comprising:
a support plate having a first surface adapted to support the substrate;
a first alignment member disposed proximate a first edge of the support plate and extending above a plane the first surface of the support plate, the first alignment member adapted to urge the substrate in a first direction;
a second alignment member disposed proximate a second edge that is opposite the first edge of the support plate, the second alignment member extending above a plane the first surface of the support plate and adapted to urge the substrate opposite first direction; and
a first cylindrical member disposed proximate a third edge that is disposed between the first edge and the second edge of the support plate, the first cylindrical member having a rotational axis aligned with the first direction.

2. The support of claim 1, wherein the first alignment member comprises a sloping face adapted to urge the substrate in the first direction.

3. The support of claim 2, wherein the sloping face define an acute angle with the first surface of the support plate.

4. The support of claim 2, wherein the sloping face and at the first surface of the support plate define an angle of between about 60 to about 80 degrees.

5. The support of claim 1, wherein the first alignment member comprises a top surface adapted to maintain the substrate in a spaced-apart relation to the first surface.

6. The support of claim 1, wherein the first alignment member comprises:
a sloping face extending above the first surface and facing a center of the support plate; and
a plateau coupled to the sloping face and extending towards the center of the support plate.

7. The support of claim 6, wherein the plateau further comprises a top surface parallel to a plane of the support plate or tapered towards the center of the support plate.

8. The support of claim 7, wherein the axis of the first cylindrical member disposed at an elevation about equal or less than an elevation of a top surface relative to the support plate.

9. The support of claim 1, wherein the axis of the first cylindrical member is parallel to a plane of the support plate and orthogonal to the first direction.

10. The support of claim 1 further comprising a second cylindrical member disposed proximate a fourth edge that is opposite the third of the support plate.

11. The support of claim 1 further comprising:
a plurality of support elements disposed on first surface of the support plate adapted to maintain the substrate in a spaced-apart relation to the support plate.

12. The support plate of claim 11, wherein the first alignment member further comprises:
a sloping face extending above the first surface and facing a center of the support plate; and
a plateau coupled to the sloping face and extending towards the center of the support plate, the plateau having an elevation greater or equal to the support elements relative to the first surface of the support plate.

13. The support of claim 11, wherein at least one of the support elements is a low friction pad or roller ball.

14. A substrate support for supporting, comprising:
a support plate having a first surface adapted to support the substrate;
a first alignment member and a second alignment member disposed proximate opposite edges of the support plate, the first and second alignment members each having a sloping face extending above a plane the first surface of the support plate and adapted to urge the substrate towards a center of the support plate along a first line defined between the first and second alignment members; and
a first cylindrical member and second cylindrical member disposed proximate opposite edges of the support plate and adapted to urge the substrate towards a center of the support plate along a second line defined between the first and second cylindrical members, where the first line is orientated at an angle to the second line.

15. The support of claim 14, wherein the first cylindrical member has a rotational axis parallel to the first direction.

16. The support of claim 14, wherein the sloping faces of the alignment members define an angle of between about 60 to about 80 degrees.

17. The support of claim 14, wherein each of the alignment members further comprises:
a top surface disposed inward of the sloping face relative to the center of the support plate and adapted to maintain the substrate in a spaced-apart relation to the first surface.

18. The support of claim 17, wherein the top surface is parallel to the plane of the support plate or tapered towards the center of the support plate.

19. The support of claim 18, wherein the axis of the first cylindrical member is disposed at an elevation about equal or less than an elevation of the top surfaces relative to the support plate.

20. The support of claim 14 further comprising:
a plurality of support elements disposed on first surface of the support plate adapted to maintain the substrate in a spaced-apart relation to the support plate, wherein at least one of the support elements is a low friction pad or roller ball.

21. The support of claim 14, wherein the first line and the second line are perpendicular.

22. A substrate support for supporting, comprising:
a support plate having a first surface adapted to support the substrate;
a first alignment member and a second alignment member disposed proximate a first edge of the support plate and adapted to urge the substrate in a first direction, the first and second alignment members each having a sloping face extending above a plane the first surface of the support plate and orientated towards a center of the support plate;
a third alignment member and a fourth alignment member disposed proximate a second edge of the support plate and adapted to urge the substrate in a direction opposite the first direction, the third and fourth alignment members each having a sloping face extending above the plane the first surface of the support plate and orientated towards the center of the support plate;
a first cylindrical member and second cylindrical member disposed proximate a third edge of the support plate, the third edge disposed between the first and second edges, the first and second cylindrical members having a rotational axis parallel to the first direction; and
a third cylindrical member and fourth cylindrical member disposed proximate a fourth edge of the support plate, the fourth edge disposed opposite the third edge, the third and fourth cylindrical members having a rotational axis parallel to the first direction.

23. The support of claim 22, wherein the sloping faces of the alignment members define an angle of between about 60 to about 80 degrees.

24. The support of claim 23, wherein each of the alignment members further comprises:
a top surface disposed inward of the sloping face relative to the center of the support plate and adapted to maintain the substrate in a spaced-apart relation to the first surface.

25. The support of claim 24, wherein the top surface is parallel to the plane of the support plate or tapered towards the center of the support plate.

26. The support of claim 25, wherein the axis of the first cylindrical member is disposed at an elevation about equal or less than an elevation of the top surfaces relative to the support plate.

27. The support of claim 22 further comprising:
a plurality of support elements disposed on first surface of the support plate adapted to maintain the substrate in a spaced-apart relation to the support plate, wherein at least one of the support elements is a low friction pad or roller ball.

28. A load lock chamber for transferring a substrate between a first environment and a second environment, the load lock chamber comprising;
a chamber body having a first substrate transfer port and a second substrate transfer port;
a support plate disposed within the chamber body and having a first surface adapted to support the substrate passed through either the first or second substrate transfer ports;
a first alignment member disposed proximate a first edge of the support plate and extending above a plane the first surface of the support plate, the alignment member adapted to urge the substrate in a first direction;
a second alignment member disposed proximate a second edge of the support plate and having an orientation of the first alignment member mirrored about a center of the support plate, the second alignment member adapted to urge the substrate in a direction opposite the first direction;
a first cylindrical member disposed proximate a third edge of the support plate, the second edge disposed between the first edge and the second edge, the first cylindrical member having a rotational axis aligned with the first direction; and
a second cylindrical member disposed proximate a fourth edge of the support plate, the fourth edge disposed opposite the third edge, the second cylindrical member having a rotational axis aligned with the first direction.

29. The chamber of claim 28, wherein the first alignment member comprises a sloping face adapted to urge the substrate in the first direction.

30. The chamber of claim 29, wherein the sloping face defines an angle of between about 60 to about 80 degrees.

31. The chamber of claim 28, wherein each of the first and second alignment members comprises:
a sloping face extending above the first surface and facing a center of the support plate; and
a plateau coupled to the sloping face and extending towards the center of the support plate.

32. The chamber of claim 31, wherein the plateau further comprises a top surface parallel to a plane of the support plate or tapered towards the center of the support plate.

33. The chamber of claim 32, wherein the axis of the cylindrical member disposed at an elevation about equal or less than an elevation of a top surface relative to the support plate.

34. The chamber of claim 28 further comprising:
a plurality of support elements disposed on first surface of the support plate adapted to maintain the substrate in a spaced-apart relation to the support plate.

35. The chamber of claim 34, wherein at least one of the support elements is a low friction pad or roller ball.

36. A load lock chamber for transferring a substrate between a first environment and a second environment, the load lock chamber comprising;
a chamber body having a first substrate transfer port and a second substrate transfer port;
a support plate disposed within the chamber body and having a first surface adapted to support the substrate passed through either the first or second substrate transfer ports;
a support plate having a first surface adapted to support the substrate;
a first alignment member and a second alignment member disposed proximate a first edge of the support plate and adapted to urge the substrate in a first direction, the first and second alignment members each having a sloping face extending above a plane the first surface of the support plate and orientated towards a center of the support plate;
a third alignment member and a fourth alignment member disposed proximate a second edge of the support plate and adapted to urge the substrate in a direction opposite the first direction, the third and fourth alignment members each having a sloping face extending above the plane the first surface of the support plate and orientated towards the center of the support plate;
a first cylindrical member and second cylindrical member disposed proximate a third edge of the support plate, the third edge disposed between the first and second edges, the first and second cylindrical members having a rotational axis parallel to the first direction; and
a third cylindrical member and fourth cylindrical member disposed proximate a fourth edge of the support plate, the fourth edge disposed opposite the third edge, the third and fourth cylindrical members having a rotational axis parallel to the first direction.

37. The chamber of claim 36, wherein the sloping faces of the alignment members define an angle of between about 60 to about 80 degrees.

38. The chamber of claim 36, wherein each of the alignment members further comprises:
a top surface disposed inward of the sloping face relative to the center of the support plate and adapted to maintain the substrate in a spaced-apart relation to the first surface.

39. The chamber of claim 38, wherein the top surface is parallel to the plane of the support plate or tapered towards the center of the support plate.

40. The chamber of claim 36, wherein the axis of the first cylindrical member is disposed at an elevation about equal or less than an elevation of the top surfaces relative to the support plate.

41. The chamber of claim 36 further comprising:
a plurality of support elements disposed on first surface of the support plate adapted to maintain the substrate in a spaced-apart relation to the support plate, wherein at least one of the support elements is a low friction pad or roller ball.
